(19) United States
(12) Patent Application Publication
(10) Pub. No.: US 2008/0073787 A1
(43) Pub. Date: Mar. 27, 2008

(54) Method forming metal interconnection filling recessed region using electro-plating technique

(76) Inventors: Jun-Hwan Oh, Incheon-si (KR); Hyoung-Sik Kim, Seoul (KR); Il-Goo Kim, Gyeonggi-do (KR); Ju-Hyuck Chung, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/655,156

(22) Filed: Jan. 19, 2007

(30) Foreign Application Priority Data
Sep. 25, 2006 (KR) 10-2006-0092864

(51) Int. Cl. H01L 23/52; H01L 21/4763

(52) U.S. Cl. 257/751; 438/687; 438/675; 438/638; 438/652; 257/762; 257/774

(57) ABSTRACT

A metal (e.g., copper) interconnect and related method of fabrication are disclosed in which the metal interconnect is formed by electro-plating a seed layer formed on a recess in a substrate before a metal layer is electro-plated to fill the recess.

### BACKGROUND

1. Field of the Invention

The invention relates generally to the fabrication of microelectronic devices. More particularly, the invention relates to a method of forming metal interconnects on a substrate using an electro-plating technique.

This application claims priority to Korean Patent Application No.10-2006-0092864, filed on Sep. 25, 2006, the subject matter of which is hereby incorporated by reference in its entirety.

2. Description of Related Art

With continuing increases in the integration density of microelectronic devices, and particularly in semiconductor memory devices, the unit sizes of the individual components formed on a substrate implementing such devices have been reduced to remarkably small dimensions. That is, as the density of circuit patterns implementing contemporary microelectronic devices on constituent substrates has increased, the dimensions of metal contacts, vias, interconnections, and similar features (hereafter, generally referred to as “interconnects”) have decreased to well below a micron. In contrast, the thickness of many material layers, such as dielectric layers, associated with interconnects has remained relatively constant. As a result, the aspect ratio (e.g., a measure of Z-direction height divided by X-direction width) of interconnects has increased to the point where fabrication engineers face significant problems forming sub-micron interconnects.

One common type of interconnect used in the fabrication of contemporary microelectronic devices is the dual-damascene structure. In a dual-damascene structure, a single metal deposition process is used to simultaneously form two related interconnects, such as metal lines and associated vias. Dual-damascene structures may be formed using a number of different process sequences.

FIGS. 1 and 2 illustrate two common process sequences used to form dual-damascene structures.

FIG. 1 illustrates a trench-first type dual-damascene process in temporal sequence from top to bottom of the drawing. First, a conductive region 12 is formed in a substrate 10. Conductive region 12 may be a metal contact or a doped polysilicon region, for example. An etch stop layer 14 is formed over substrate 10 including conductive region 12 and an insulating layer 16 is formed on etch stop layer 14.

Next, using conventional mask and etch methods, a trench opening 18 is patterned into insulating layer 16. A photo-resist layer 20 is then formed on patterned insulating layer 16 to selectively expose a portion of insulating layer 16 in which a via opening will be formed. Using photo-resist layer 20 as an etch mask, via opening 21 is formed in insulating layer 16.

Via opening 21 and, trench opening 18 are now simultaneously filled with a metal layer 22. Once metal layer 22 has been planarized using, for example, a Chemical-Mechanical Polishing (CMP) process, metal via 24a and metal line 24b are complete.

FIG. 2 illustrates a via-first type dual-damascene process. As above, conductive region 12 is formed in substrate 10, etch stop layer 14 is formed on substrate 10 including conductive region 12, and insulating layer 16 is formed on etch stop layer 14. Using conventional photolithography and etch methods, via opening 21 is first patterned into insulating layer 16. Photo-resist layer 20 is then formed on patterned insulating layer 16 to selectively expose a portion of insulating layer 16 in which a trench opening will be formed. Using photo-resist layer 20 as an etch mask, trench opening 18 is formed in insulating layer 16. Via opening 21 and trench via 18 are again simultaneously filled with metal layer 22. After being planarized, metal via 24a and metal line 24b are complete.

For several years now, copper or copper alloys have been used as the metal of choice in the fabrication of interconnects. Copper and alloys including copper (hereafter collectively and specifically referred to as “copper material”).exhibit lower resistivity and higher electro-migration resistance than other metals such as aluminum. These properties are important because they allow the higher current densities and faster operating speeds required by contemporary microelectronic devices.

However, the use of copper material to form interconnects having very narrow line widths and/or high aspect ratios presents many challenges. For example, previously used fabrication processes, such as Chemical Vapor Deposition (CVD), may not be effectively used to deposit copper material. This is particularly true when copper is used to fill high aspect ratio recesses defining the interconnects used in contemporary designs. As a result of these inadequacies, electro-plating or electro-deposition processes have been used to fill such recesses with copper material.

Electro-plating is an old technique newly adapted to the problem of depositing copper material on substrates. Electro-plating uses an electrolyte containing positively charged ions supplied from a deposition material source (e.g., a plate of copper material). A negatively charged substrate on which a target (e.g., a seed layer) adapted to receive metal ions provided from the deposition material source is then exposed to the electrolyte. An applied electrical potential develops an electric field which facilitates the migration of metal ions from the deposition material source to target through the electrolyte.

One notable challenge associated with the use of copper material to form interconnects within Ultra Large Scale Integration (ULSI) devices is the reliability of a seed layer used as an electro-plating target. The coverage and surface qualities of a seed layer deposited on an interconnect recess and adapted to receive a metal layer via an electro-plating process is highly significant to the overall performance attributes of the resulting interconnects. That is, during the initial stages of copper material electro-plating onto a seed layer, a non-uniform distribution of an associated electric field is possible due to a number of factors. Any void or imperfection in the underlying seed layer taken in conjunction with non-uniformly applied electric fields have the potential to impair the early stage morphology of the deposited metal layer.

Consider, for example, one conventional approach to the formation of a metal interconnect described in relation to FIG. 3. Here, an insulating layer 16 is formed on a substrate 10. A recess 27 having a high aspect ratio (a/b) is formed in insulating layer 16 to expose a portion of substrate 10. Before a metal material can be effectively electro-plated to fill recess 27, a seed layer 7 must first be provided. However, a diffusion barrier layer 5 preventing the unwanted migration of metal atoms into insulating layer 16 and/or substrate 10 is typically formed before seed layer 7. Various conventionally understood processes may be used to form barrier layer 5 on insulating layer 16 including recess 27.

Seed layer 7 may be formed on barrier layer 5 using a Physical Vapor Deposition (PVD) process, such as sputtering. Despite the fact that conventionally available PVD processes provide relatively poor step coverage, a PVD process is typically preferred over a CVD process, since CVD processes provide a seed layer 7 having very poor adhesion properties to barrier layer 5. The term “step coverage” denotes a uniformity of thickness quality for a given material layer as it is formed over an underlying structure. Step coverage has particular significance in the context of underlying structures having complex geometries that resist even deposition coverage, such as high aspect ratio recesses.

For example, in the illustrated example of FIG. 3, the step coverage of seed layer 7 is marginal at best. Note, the relatively thin coverage (T1) of the lower sidewall portions of recess 27 verses the thicker coverage (T2) of seed layer 7 on the upper corner portions of recess 27. This ratio of T2/T1 defines the poor step coverage property of seed layer 7. Indeed, in the illustrated example, seed layer 7 is formed with pronounced overhangs (OH) on the upper corner portions of recess 27. The term “overhang” in this context is used to generally indicate a relatively thicker portion of a material layer. Overhangs adversely affect the step coverage of a material layer and are commonly, but not exclusively, formed on corner step and upper corner portions of underlying structures, such as recesses. In the example illustrated in FIG. 3, the upper corner portions of recess 27, as well as the vertical-to-horizontal-to-vertical sidewall portions of the trench/via structures (see, FIGS. 1 and 2) are examples of recess portions likely to develop seed layer overhangs. However, the term “corner step portion” may be applied to any portion of an underlying structure having a geometry that results in poor step coverage of a subsequently formed material.

As the aspect ratio of interconnects increases, the difficulties associated with maintaining acceptable step coverage also increases. That is, with reference to the illustrated example of FIG. 3, as the aspect ratio (a/b) of recess 27 increases the relatively sidewall thickness (T1) of seed layer 7 tends to decrease relative to more thickly deposited portions of seed layer 7 like those formed on the upper working surface of substrate 10 and the upper corner portions of recess 27. A malformed seed layer (e.g., a seed layer having poor step coverage) presents multiple problems to the successful formation of an overlaying metal layer filing recess 27 and forming the desired metal interconnect.

Consider a subsequent applied processing example described in relation to FIG. 4. FIG. 4 schematically illustrates a conventional electro-plating process applied to substrate 10 shown in FIG. 3. This process may be performed in a wet bath 11 including a deposition metal source plate 15 immersed in an electrolyte solution 13. Substrate 10 having a seed layer 7 formed over recess 27 is exposed to electrolyte solution 13 with a voltage power source connected between substrate 10 and deposition metal source plate 15. Namely, opposing ends of substrate 10 are commonly connected to the negative (anode) terminal of voltage power source 17 and the deposition metal source plate 15 is connected to the positive (cathode) terminal.

Under the electromotive influence of an electric (“E”) field generated between substrate 10 and deposition metal source plate 15, metal ions from deposition source metal plate 15 migrate through electrolyte solution 13 and accumulate on seed layer 7. In this manner, a metal layer having a composition related to that of deposition metal source plate 15 is formed on seed layer 7.

Unfortunately, however, the E-field is not uniformly applied across the working surface of substrate 10 and seed layer 7. As indicated in FIG. 4, edge portions (E1) of the E-field applied to substrate 10 are greater than a center portion (E2). This field variance is referred to as “terminal effect” and it may cause a relatively greater accumulation of metal ions on portions (EG) of substrate 10 located within the edge portions (E1) of the E-field, as compared with a center portion (CT) of substrate 10 located within the center portion (E2) of the E-field. This variable relationship between the deposition thickness (THK) of the metal layer relative to substrate position (P) is illustrated in FIG. 5.

The terminal effect, which is present in all practical electro-plating processes to a greater or lesser extent, is exacerbated when a very thin seed layer is used as an electroplating target. That is, with reference to the examples shown in FIGS. 3 and 4, as the thickness of seed layer 7 varies so too does its inherent resistivity. Reduced resistivity of a relatively thinner seed layer 7 tends to amplify differences (e.g., E1 verse E2) in the E-field induced current that controls the rate of electroplating. As a result, the metal layer formed on seed layer 7 is non-uniform in its composition (i.e., exhibits poor step coverage) with portions of the electro-plated metal layer located at the edge portions of substrate 10 being thicker than centrally located portions.

When seed layer 7 includes overhangs, such as those shown in FIG. 3, the non-uniform formation of a subsequently formed metal layer may actually result in the formation of a void within recess 27 as metal ions forming on the overhangs bridge-over recess 27 rather than evenly fill it from the bottom surface upwards. Additionally, some recesses associated with centrally located interconnects on a substrate may not be adequately filled with metal during the electro-plating process while recesses associated with peripherally located interconnects may be over-filled. This uneven topology may require additional processing to avoid the possibility of short-circuiting adjacent peripherally located interconnects and leaving open circuits between intended connections to centrally located interconnects.

### SUMMARY OF THE INVENTION

In one embodiment, the invention provides a method of forming a metal interconnect, comprising; forming an insulation layer on a substrate, forming a recess in the insulating layer, forming a seed layer on the recess, and electro-polishing the seed layer, before filling the recess with metal material.

In another embodiment, the invention provides a method of forming a metal interconnect in a recess formed in a substrate and prepared with a seed layer, the method comprising; electro-polishing the seed layer by immersing the substrate in a first electrolyte solution and applying a voltage of first polarity between the substrate and a first deposition metal source plate, and thereafter, filling the recess with metal material.

In another embodiment, the invention provides a method of forming a metal interconnect in a recess formed in a substrate, the recess comprising a bottom surface connected to a sidewall surface, and upper corner portions respectively connecting the sidewall surfaces to an upper surface of the substrate, the method comprising; forming a seed layer of sufficient thickness to completely cover the recess, and thereafter, electro-polishing the seed layer to a substantially uniform thickness by applying an electric field, the electric field being more concentrated at the upper corner portions of the recess than at the bottom or sidewall surfaces of the recess.

In another embodiment, the invention provides a method of forming a copper interconnect, comprising; forming a recess in an insulation layer formed on a substrate, forming a seed layer of sufficient thickness to completely cover the recess, selectively removing overhangs formed in the seed layer to produce a polished seed layer having a substantially uniform thickness, and thereafter, filling the recess with copper material.

In another embodiment, the invention a copper interconnect formed in a recess, the recess being formed in an insulating layer formed on a substrate, the copper interconnect comprising; an electro-polished seed layer of substantially uniform thickness formed on bottom and sidewall surfaces of the recess, and copper material electro-plated onto the electro-polished seed layer to fill the recess.

### BRIEF DESCRIPTION OF THE DRAWINGS

Embodiments of the invention will be described herein with reference to the accompanying drawings in which like reference numbers and symbols indicate like or similar elements throughout. In the drawings:

FIG. 1 illustrates a conventional process sequence adapted to form a trench-first dual damascene structure;

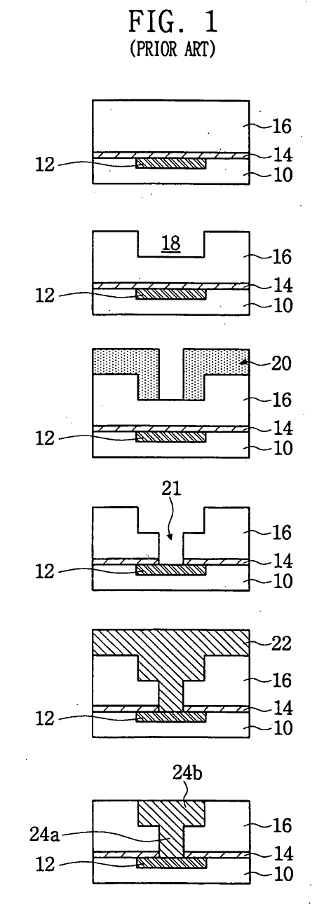

FIG. 2 illustrates a conventional process sequence adapted to form a via-first dual damascene structure;

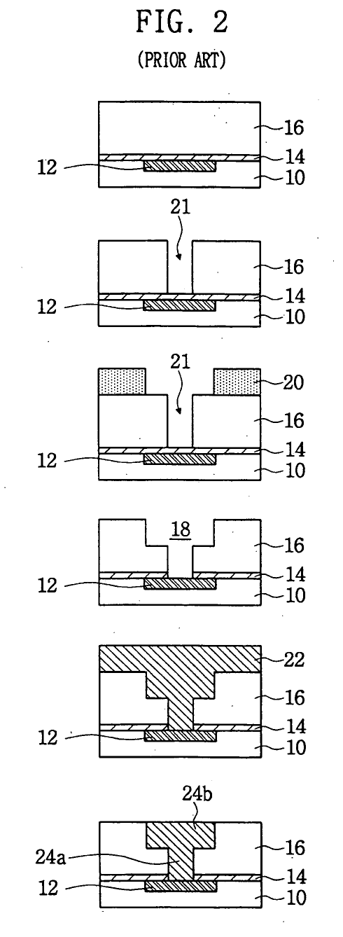

FIG. 3 is a cross-sectional view illustrating certain aspects of the formation of a conventional interconnect;

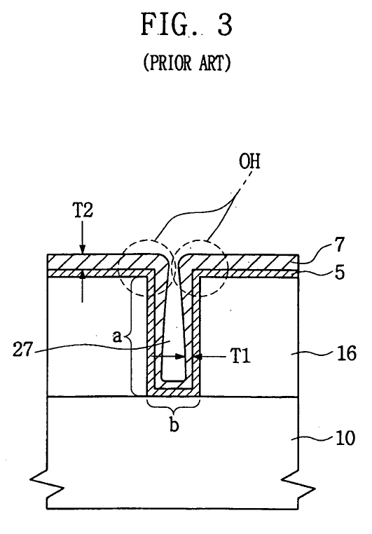

FIG. 4 is a schematic illustration of wet bath apparatus useful in the electro-plating of a metal layer during the fabrication of a conventional interconnect;

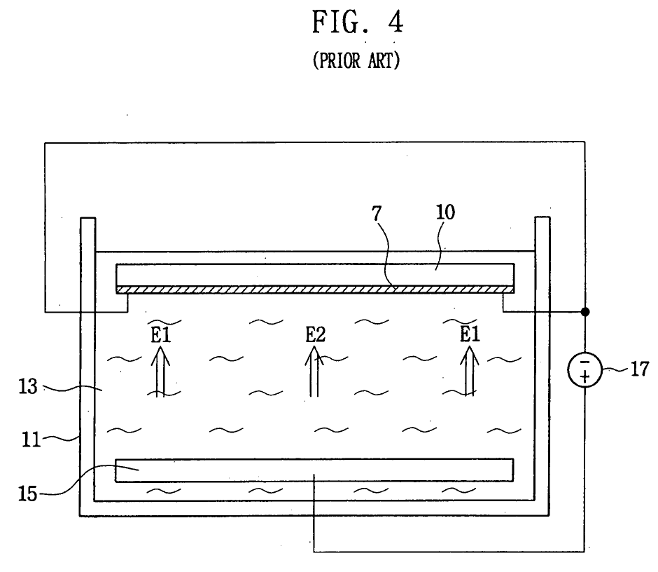

FIG. 5 is a graph illustrating the terminal effect in relation to the formation of a metal interconnect;

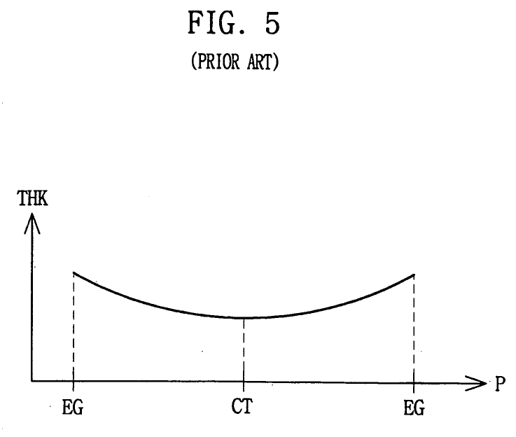

FIG. 6 is a flowchart illustrating a method embodiment of the invention;

FIG. 7 is a cross-sectional view illustrating seed layer formation during the fabrication of an interconnect consistent with an embodiment of the invention;

FIG. 8 is a schematic illustration of wet bath apparatus useful in the electro-polishing of a seed layer during the fabrication of an interconnect consistent with an embodiment of the invention;

FIG. 9 is a cross-sectional view illustrating electro-polishing of a seed layer during the fabrication of an interconnect consistent with an embodiment of the invention;

FIG. 10 is a cross-sectional view further illustrating electro-polishing of a seed layer during the fabrication of an interconnect consistent with an embodiment of the invention;

FIG. 11 is a schematic illustration of wet bath apparatus useful in the electro-plating of a metal layer and/or the electro-polishing of a seed layer during the fabrication of an interconnect consistent with an embodiment of the invention;

FIG. 12 is a cross-sectional view illustrating fabrication of an interconnect consistent with an embodiment of the invention;

FIG. 13 is a schematic diagram illustrating certain additives that may be added to an electrolyte solution used during the electro-plating of a metal layer and/or the electro-polishing of a seed layer during the fabrication of an interconnect consistent with an embodiment of the invention; and

FIG. 14 is a cross-sectional view illustrating fabrication of an interconnect consistent with an embodiment of the invention.

### DESCRIPTION OF EMBODIMENTS

Embodiments of the invention will be described in some additional detail with reference to the accompanying drawings. The present invention may, however, be embodied in different forms and should not be constructed as limited to only the embodiments set forth herein. Rather, these embodiments are presented as teaching examples. Throughout the written description and drawings, like reference numbers and symbols refer to like or similar elements.

Certain drawing dimensions, particularly those related to elements, layers and regions of the exemplary interconnects described below may have been exaggerated for clarity. It will also be understood that when a layer is referred to as being ‘on’ another layer, element, or region, it may be “directly on” the other layer, element, or region, or intervening layers may also be present. Further, it will be understood that when a layer is referred to as being ‘under’ another layer, it may be “directly under”, or one or more intervening layers may be present. In addition, it will also be understood that when a layer is referred to as being ‘between’ two layers, elements, or regions, it may be the only layer there between, or one or more intervening layers may also be present.

Moreover, terms such as “first,” and “second” are used to describe various layers, elements, and regions in various embodiments of the invention, but such terms do not temporally or sequentially limit (e.g., in an order of formation) the related layers, elements, and regions. Rather, these terms are used merely to distinguish one layer, element or region from another.

Embodiments of the invention have broad applications across a range of microelectronic devices and related fabrication techniques. Certain embodiments of the invention find applications in various classes of microelectronic devices—many of which have recently undergone a fabrication transition from aluminum to copper in relation to the formation of their constituent interconnects. A noted in passing above, this transition from aluminum to copper as the metal of choice for the fabrication if metal interconnects is directly related to ongoing reductions in the size of circuit patterns and circuit pattern elements and components. Such circuit patterns require the formation of thinner and smaller interconnects, many of which have higher aspect ratios and/or increased resistivity.

In the context of semiconductor memory devices—as one exemplary class of microelectronic devices—copper interconnects have been used beginning generally with 130 nm scale devices and on through 90 nm, 65 nm, and 45 nm scale devices. Beginning materially with 90 nm scale devices, ultra-low K dielectric materials have been used in conjunction with copper interconnects. This combination of high aspect ratio interconnects formed from copper material and ultra low K dielectric material layers within semiconductor memory devices is just one example where embodiments of the invention find application.

The term “cooper material” refers to essentially pure copper which is commonly used as a seed layer in electroplating processes and copper alloys which are used in multiple applications requiring stress mitigation within interconnects. Commonly used copper alloys include, for example, those containing 1% aluminum. Other metals of varying composition percentages are also contemplated within the scope of the present invention. Indeed, different applications and fabrication sequences will require the use of metal materials having different mechanical and electrical properties. Thus, while many of the following embodiments are drawn to examples incorporating copper material, the scope of the invention is not limited to only copper materials.

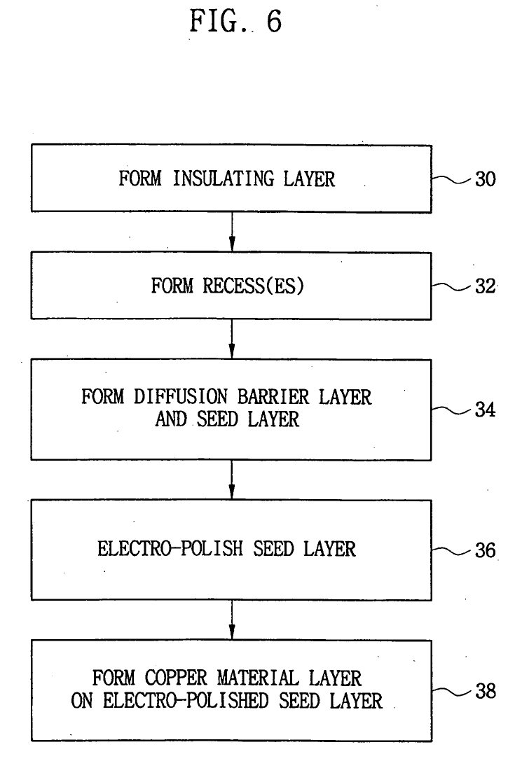

One method embodiment of the invention is illustrated in the flowchart shown in FIG. 6. This exemplary sequence of fabrication processes adapted to the formation of an improved metal interconnect begins with the formation of one or more insulating layer(s) on a substrate (30). The substrate may be formed from a semiconductor material, a semi-insulating material, a silicon-on-insulator material, a glass, or ceramic material, etc. The insulating layer may be a dielectric layer.

A recess or collection of recesses is then formed in the insulating layer (32). The recess may be a simple via or trench opening, or a recess having a more complex geometry, such as one adapted to the formation of a dual damascene structure.

Once the recess has been formed in the insulating layer, a diffusion barrier layer and a seed layer are sequentially formed on the substrate including the recess (34). In certain applications, it may not be necessary to form a barrier layer between the seed layer and the insulating layer and/or substrate. In such applications, the use of a barrier layer is considered optional to embodiments of the invention. However, in many applications the migration of metal atoms from the seed layer and/or the subsequently formed metal layer has a decidedly negative effect on the performance properties of the surrounding layer(s) and region(s), such as the insulating layer and/or conductive regions (e.g., drains and sources) in the substrate. Accordingly, one or more barrier layer(s) is commonly interposed between the insulating layer and/or substrate and the seed layer.

Following its formation on the barrier layer, the seed layer is electro-polished (36). Electro-polishing, as described in some additional detail below, is designed to selectively remove metal material from the seed layer in order to form a polished seed layer having improved step coverage. In certain embodiments, overhangs formed on corner step and/or upper corner portions of a recess are reduced in size (e.g., reduced in their relative thickness) or entirely eliminated by the electro-polishing process.

After electro-polishing of the seed layer, a copper material layer is formed on the polished seed layer using an electro-plating process (38) to fill the recess.

A metal interconnect formed in accordance with the foregoing embodiment is significantly less likely to include voids in the metal fill layer, since electro-plating occurs over a very uniform seed layer. As a result, the terminal effect inherent in the electro-plating process is substantially mitigated.

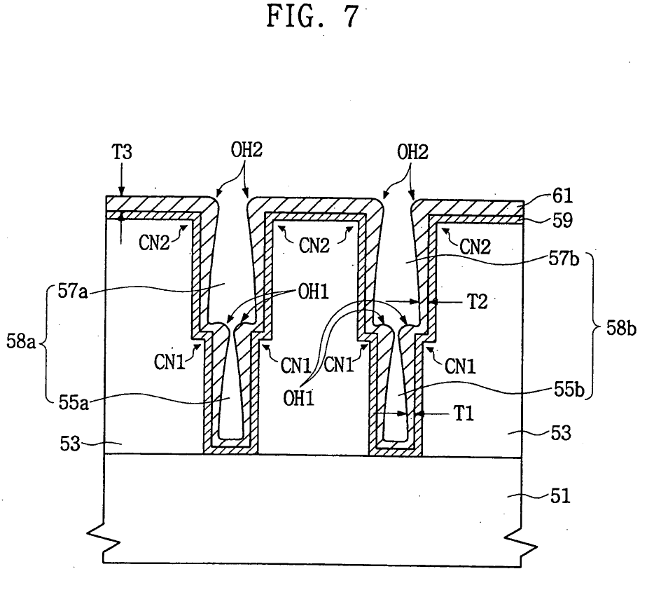

The foregoing method embodiment will be further described in the context of a dual-damascene structure shown in FIG. 7. In this example, an insulating layer 53 is formed on a substrate 51. Thereafter, first and second recesses 58a and 58b are formed in insulating layer 53 using one of several known fabrication sequences (e.g., a trench-first or via-first type dual-damascene process). However formed, first recess 58a comprises a first via opening 55a and a first trench opening 57a formed over first via opening 55a. Second recess 58b similarly comprises a second via opening 55b and a second trench opening 57b formed over second via opening 55b. The term “over” in this context has reference to the illustrated example in which substrate 51 is identified as a “bottom” vertical reference and subsequently formed material layers, elements and regions being built “up” therefrom.

Following formation of first and second recesses 58a and 58b, a diffusion barrier layer 59 is formed over substrate 51. Barrier layer 59 will include one or more materials designed to prevent migration of metal atoms into substrate 51 and/or insulating layer 53. Such material(s) will vary with the composition of the metal layer, the seed layer, the insulating layer(s) and/or the substrate material. However, examples of barrier layer materials that may be used alone or in combination include; tantalum (Ta), tantalum nitride (TaN), tantalum carbide (TaC), tantalum silicon nitride (TaSiN), titanium nitride (TiN), titanium silicon nitride (TiSiN), tungsten nitride (WN), and/or tungsten carbide (WC). Barrier layer 59 may be formed using a number of conventionally understood fabrication processes, such as a competent PVD process performed under conditions determined by specific application and choice of barrier layer material(s).

After formation of barrier layer 59, a seed layer 61 is formed. In most applications, both barrier layer 59 and seed layer 60 will have conformal profiles over the underlying structure of substrate 51, including first and second recesses 58a and 58b. Seed layer 61 may be formed from any metal bearing material, but commonly used materials include essentially pure copper, a copper alloy, and/or tungsten. In this context, the phrase “essentially pure” means a copper material that is as pure as reasonably possible under commercial circumstances.

It is important that seed layer 61 be formed without voids exposing any portion of the underlying structure. The operative principles of electroplating generally provide for the transfer of metal atoms from the deposition metal source to the seed layer will occur much more easily than the transfer of metal atoms to the underlying barrier layer or insulating material. Indeed, seed layer 61 will be selected for its affinity to and ready adhesion with migrating metal atoms from the deposition metal source. As a result, metal atoms transferred via an electrolyte solution will readily bond with seed layer 61. This is not necessarily true of barrier layer 59 and insulating layer 53. Thus, any void formed in seed layer 61 and exposing underlying barrier layer 59 and/or insulating layer 53 will result in a corresponding spatial absence (a material void or morphology discontinuity) of metal atoms within the ultimately deposited metal layer. Such voids and discontinuities will adversely affect the performance properties (e.g., resistivity) of the metal interconnect. Such consequences militate towards fabrication decisions that serve to ensure full coverage of the underlying structure by seed layer 61.

One such fabrication decision might be a determination to form seed layer 61 more thickly than might otherwise be required. Extra thick deposition of seed layer 61 decreases the possibility of voids in this layer. That is, seed layer 61 may be formed with a thickness (T3) greater than a minimal thickness (T2 or T1) required for seed layer 61 to properly serve as an initial adhesion layer for transferred metal atoms. Of course, formation of a relatively thick seed layer has some distinct disadvantages in addition to the salutary effects of full coverage. Namely, significant overhangs (OH1 and OH2) are formed, respectively, on corner step and upper corner portions (CN1 and CN2) of first and second recesses 58a and 58b. Fortunately, the electro-polishing process subsequently applied to the seed layer substantially remediates this potential problem with overhangs. In other words, the poor step coverage and any excessive thickness of seed layer 61 may be remedied by application of an electro-polishing process. (Note, the poor step coverage is defined by the differing thicknesses T1, T2, and T3 of seed layer 61 in the illustrated example of FIG. 7).

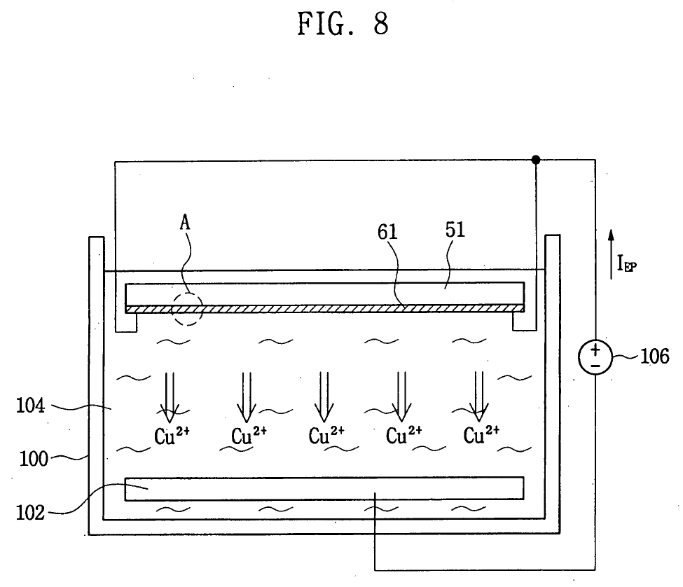

In one embodiment, the electro-polishing process may be performed in a first wet bath 100 shown in FIG. 8. First wet bath 100 immerses, wholly or in part, a deposition metal source plate 102 in a first electrolyte solution 104. The deposition metal source plate 102 may be provided with any reasonable shape or size, but it will include a metal material designed to electroplate onto seed layer 61 through first electrolyte solution 104 under the influence of an applied E-field.

First electrolyte solution 104 may be variously constituted in relation to the metal material being used, a desired rate of material transfer, etc. However, in one embodiment where copper atoms are transferred from seed layer 61 to deposition metal source plate 102, first electrolyte solution 104 may comprise at least one solution component selected from a group of solution components consisting of phosphorus acid (H3PO3), sulfuric acid (H2SO4), sulphamic acid (H2NSO3H), copper cyanide (CuCN), and pyrophosphate acid (H4P2O7), for example. As will be described in some additional detail hereafter, first electrolyte solution 104 may also comprise certain additives designed to enhance or diminish the properties of the electro-polishing process.

With a properly constituted first electrolyte solution 104, substrate 51 may be immersed, wholly or in part, and a voltage power source 106 connected between substrate 51 and deposition metal source plate 102. An electro-polishing current flow IEP is induced between deposition metal source plate 102 and substrate 51. Under the influence of the resulting electric field, copper material ions (indicated in the example as Cu2+ atoms) are transferred from seed layer 61 to deposition metal source plate 102. That is, copper metal ions are dissolved from seed layer 61 into first electrolyte 104 and transferred to deposition metal source plate 102 where they are absorbed (atomically bonded) into the lattice of atoms forming deposition metal source plate 102. The effect of this migration of copper metal ions is one of electro-polishing seed layer 61.

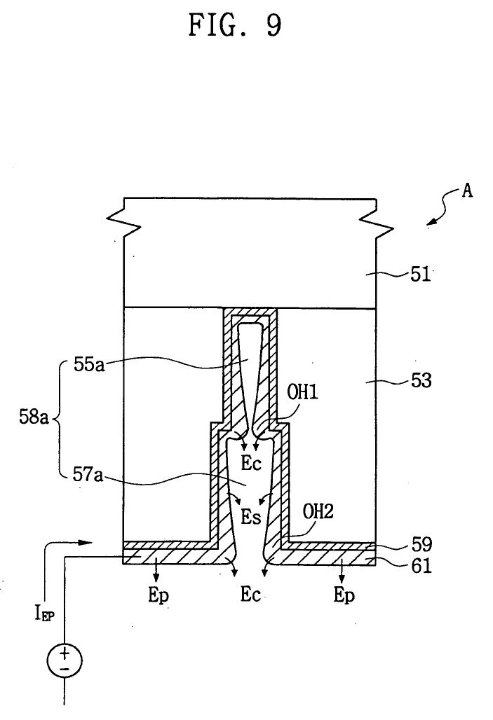

The electro-polishing process is further illustrated in FIG. 9. Here, the portion “A” of substrate 51 indicated in FIG. 8 is shown in greater detail. In FIG. 9, substrate 51 is held “upside down” and exposed to first electrolyte 104 in first wet bath 100. Portion “A” of substrate 51 includes first recess 58a comprising first via opening 55a and first trench opening 57a. Seed layer 61 formed on barrier layer 59 includes overhangs OH1 and OH2. When substrate 51 is connected to the positive terminal and deposition metal source plate 102 is connected to the negative terminal of voltage power source 106, a circuit loop is formed through electrolyte 104 and the electro-polishing current IEP flows. Accordingly, an electro-polishing E-field is induced across the surface of substrate 51, and more particularly across the face of seed layer 61.

However, the electro-polishing E-field is not evenly concentrated across the face of seed layer 61. Rather, the induced electro-polishing E-field is concentrated by both the geometry and relative resistivity of seed layer 61. For example, as shown in FIG. 9 in relation to the geometry of first recess 58a and the relative thickness (and associated resistivity) of seed layer 61, the electro-polishing E-field includes corner portions (Ec), planar portions (Ep), and sidewall portions (Es).

Assuming the illustrated orientation between substrate 51, deposition metal source plate 102, and voltage power source 106 shown in FIGS. 8 and 9, for example, the corner portion E-field (Ec) will be notably stronger than the planar portion E-field (Ep) and the sidewall portion E-field (Es). That is, the geometry (e.g. the curved corner profile) of overhangs OH1 and OH2 in seed layer 61 as well as the increased resistivity of overhangs resulting from their greater relative thickness tend to concentrate the applied E-field. As the E-field is more concentrated at the overhangs formed on corner step and upper corner portions (CN1 and CN2) of first recess 58a, the electro-polishing effect at these points is greater than the electro-polishing effects at planar and sidewall portions of seed layer 61. In effect, relatively more copper material is removed from the thicker and geometrically pronounced overhang portions of seed layer 61.

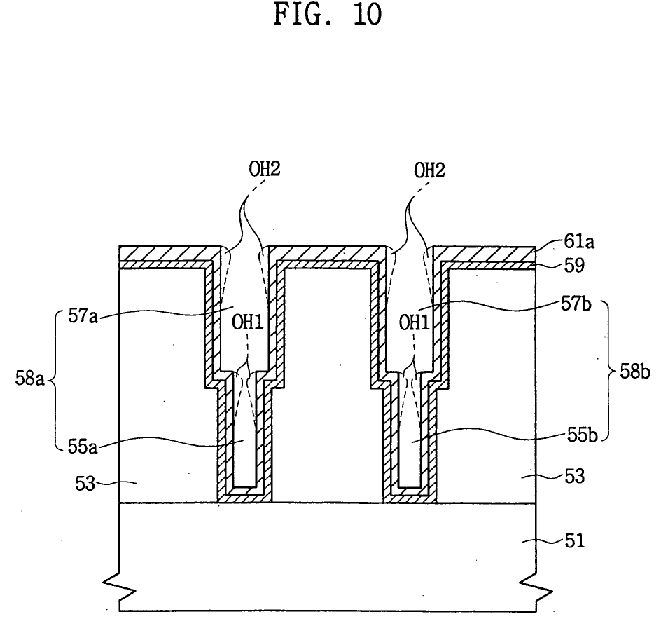

The result of this uneven polishing of seed layer 61 is further illustrated in FIG. 10. Here, substrate 51 is shown right-side up following completion of the electro-polishing process. Polished seed layer 61a is significantly more uniform in its thickness (i.e., has improved step coverage) than originally deposited seed layer 61. Overhangs OH1 and OH2 have been removed and a more uniformly thick polished seed layer having a constant resistivity is ready to receive a metal layer.

Electro-polishing of a seed layer before electroplating of a metal layer to fill an interconnect allows a relatively thick seed to be initially formed. This relatively thick seed layer ensures complete coverage of a recess associated with the interconnect, even if the recess has a complex geometry. Nonetheless, by electro-polishing the seed layer, subsequent problems related to the formation of the metal layer due to overhang bridging, skewed metal fill rates caused by terminal effects in relation to varying seed layer resistivity, etc., may be avoided.

The formation thickness, the polished thickness, and the rate of polishing provided by electro-polishing current IEP are matters of design choice made in relation to application, the composition of the metal layer and seed layer, etc. However, embodiments of the invention have been successfully implemented for seed layers and metal layers including copper material using electro-polishing currents IEP ranging from between about 1 mA/cm2 to 50 mA/cm2, and applied to a substrate immersed in a competent electrolyte solution for a period ranging from between 1 to 50 seconds.

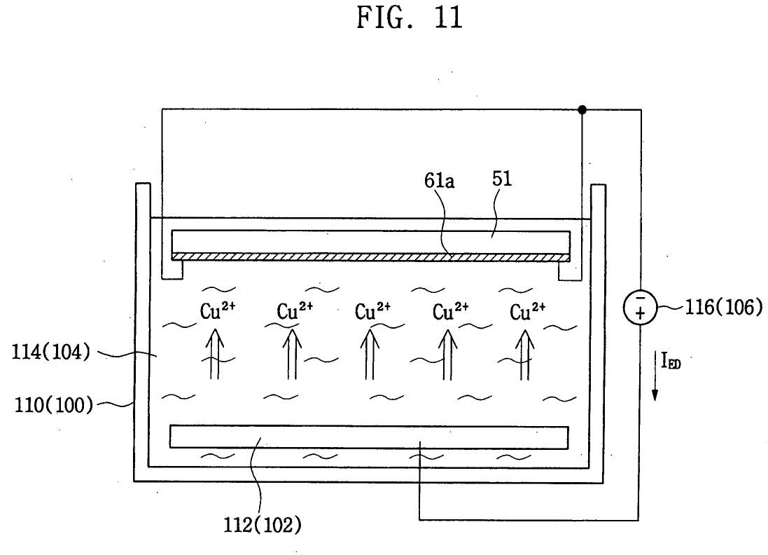

With the seed layer electro-polished, a metal layer may now be formed to fill recesses associated with the metal interconnects. In certain embodiments of the invention, an electroplating process is used with good effect to form a metal layer on the electro-polished seed layer. FIG. 11 will be used to illustrate exemplary embodiments of the invention directed to the post-electro-polishing formation of a copper material layer using an electro-plating technique.

In FIG. 11, a wet bath containing an electrolyte solution is provided to receive substrate 51 having a polished seed layer 61 a formed thereon. Substrate 51 and a deposition metal source plate are again connected to a voltage power source. In one embodiment, it is assumed that first electrolyte 104 is not only suitable for the applied electro-polishing process, but also the following electro-plating process. The “suitability” of first electrolyte 104 as between these two processes will be defined in large part by the presence (or absence) of certain additives adapted to enhance or diminish electro-polishing and/or electro-plating properties.

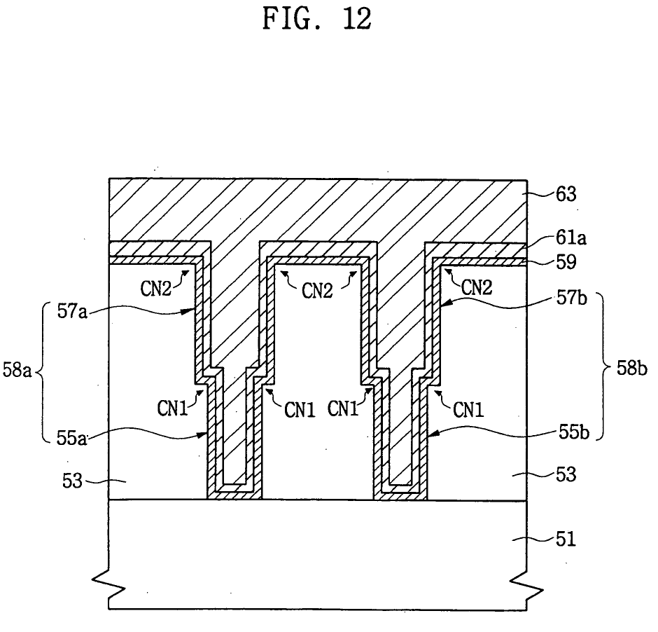

Thus, where first electrolyte 104 contain additives making it suitable for both electro-polishing and electro-plating processes, a single wet bath apparatus 100 may be used to perform both processes. In such embodiment, voltage power source 106 is capable of applying a voltage of either first polarity or second polarity (opposite the first polarity) to substrate 51. In the illustrated example which assumes the use of a copper material for seed layer 61 and metal layer 63 (see, FIG. 12), the first polarity applied during the electro-polishing process is defined by connecting the positive terminal of voltage power source 106 to substrate 51 and the negative terminal of voltage power source 106 to deposition metal source plate 102 (see, FIG. 8). The second polarity applied during the electro-plating process is defined by connecting the positive terminal of voltage power source 106 to deposition metal source plate 102 and the negative terminal of voltage power source 106 to substrate 51 (see, FIG. 11).

Under the influence of the first polarity, an electro-polishing current IEP flows towards substrate 51. In contrast, under the influence of the second polarity, an electro-plating (or electro-deposition) current IED flows towards deposition metal source plate 102. The use of a single wet bath apparatus to sequentially perform the electro-polishing and electro-plating processes by merely reversing the voltage polarity (and additionally changing the amplitude of the voltage, as needed) supplied by voltage power source 106 is very efficient in terms of fabrication facility floor space utilization and in terms of fabrication sequence processing, as this approach requires little or no substrate transport and handling between different wet baths performing electro-polishing and electroplating.

However, other embodiments of the invention benefit from the application of different electrolyte solutions, each electrolyte solution being specifically tailored to either the electro-polishing or electro-plating process. For example, following electro-polishing in first wet bath 100 described in relation to FIG. 11, a second wet bath 110 may be provided to perform electro-plating. Second wet bath 110 may make use of a second electrolyte solution 114, different from the first electrolyte solution 104. A second deposition metal source 112 provided in second wet bath 110 may be similar or different in its material composition than first deposition metal source 102. The use of a tailored second electrolyte solution and/or a second deposition metal source may increase the efficiency of the electro-plating process.

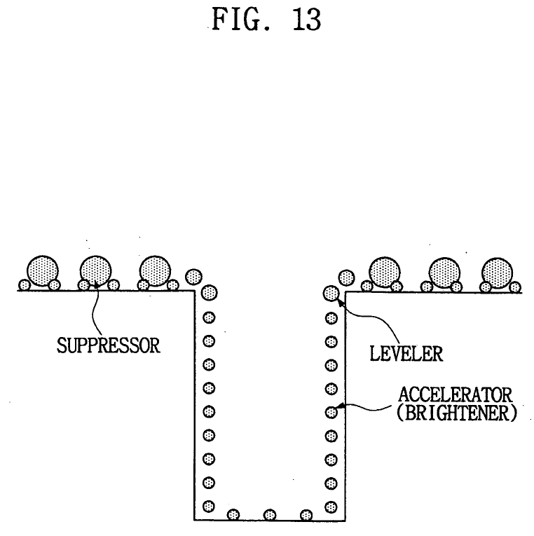

The properties of one or more of the electrolyte solutions applied to the electro-polishing of seed layer 61 and/or the electro-plating of metal layer 63 may be modified by the inclusion of one or more additives. Such additives may be generally classified as suppressors, brighteners (or accelerators), and levelers. The influence of these additives on the electro-polishing of the seed layer and/or the electro-plating of the metal layer is schematically illustrated in FIG. 13.

Suppressors include such polymers as poly-ethylene glycol (PEG) and poly-vinyl pyrrolidone (PVP). These compounds have relatively large molecules that tend to settle on the planar working surface of the seed layer. In this position, suppressors form a current suppressing film that selectively inhibits the removal of seed layer material during electro-polishing and the deposition of metal layer material during electro-plating. Suppressors are not strongly dependent on their rate of mass transfer in this regard. Suppressors also serve to inhibit the absorption of metal ions by the underlying insulting layer or substrate.

Brighteners include thiourea and mercapto propane sulfuric acid. These compounds have small molecules that readily spread across even very small surface geometries of the seed layer (e.g., within recesses). These compounds contain pendant sulfur atoms that locally enhance E-field induced current at a defined voltage. As such, brighteners accelerate the removal of seed layer material during electro-polishing and deposition of metal layer material during the electro-plating.

Levelers include polyimine and polyamide compounds having medium size molecules. They are mass transfer dependent and tend to even out the removal and disposition of seed layer and metal layer materials at the corner step and upper corner portions of a recess during electro-polishing and electroplating processes.

FIG. 12 shows substrate 51 following deposition of metal layer 63 on electro-polished seed layer 61a. When compared to the example shown in FIG. 7, the difference in seed layer step coverage from the resulting benefits to the deposition of metal layer 63 are readily manifest. Of further note, portions of metal layer 63, electro-polished seed layer 61a, and barrier layer 59 are formed on the planar working surface of substrate 51. As these portions are generally unwanted at this point in the fabrication sequence, they may be removed to complete formation of the metal interconnects before subsequent processing of substrate 51 takes place. Removal of these unwanted portions is typically accomplished by application of a conventional CMP process.

Prior to application of the CMP process to planarize the working surface of substrate 51 and remove unwanted portions of metal layer 63, electro-polished seed layer 61a, and barrier layer 59, however, metal layer 63 may be annealed to increase material grain size within the metal layer. CMP processing of metal layer 63 (and additionally electro-polished seed layer 61a) is facilitated by the increased grain size provided by the annealing process.

Either a rapid thermal annealing process or a furnace annealing in a vacuum environment may be used to anneal metal layer 63. Rapid thermal annealing is conventionally understood and may be conducted at temperatures ranging from between about 150 to 400° C. over a relatively short period of time. In contrast, furnace annealing, also a conventionally understood process, may be conducted at a lower temperature (e.g., 100 to 200° C.) for longer periods of time (e.g., 30 to 60 minutes).

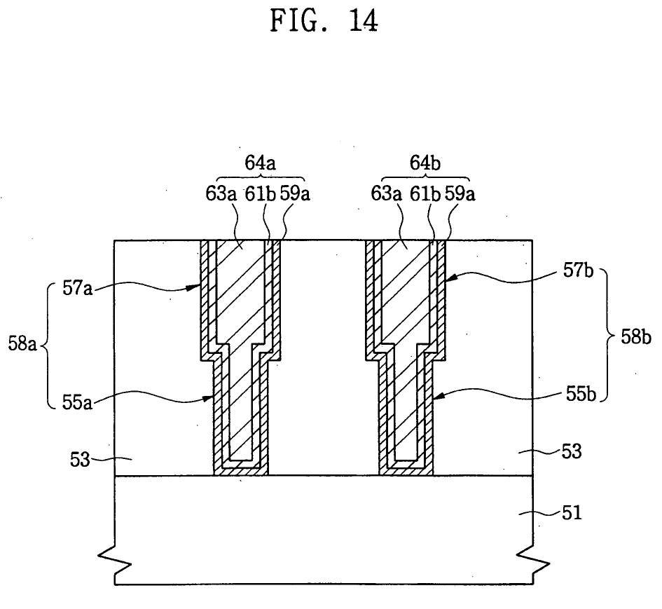

FIG. 14 shows substrate 51 following completion of first and second metal interconnects 64a and 64b formed respectively in first and second recesses 58a and 58b. Each metal interconnect 64a and 64b comprises a barrier layer (59a), polished seed layer (61b) and metal fill layer (63a). Polished seed layer 61b does not include overhangs or voids and metal fill layer is evenly and homogenously formed within the recess without voids or gross discontinuities.

The metal interconnects provided by embodiments of the invention thus provide consistently high performance. Embodiments of the invention are particularly well adapted to the formation of metal interconnects formed from copper material, but any reasonable metal composition may be used. Metal interconnects having a high aspect ratio may nonetheless be fabricated without the process variations that impair the performance of similar metal interconnects fabricated using conventional approaches.

The invention has been described above in the context of several specific example embodiments. Dual-damascene recesses adapted to the formation of metal lines and associated vias have been used in several of these embodiments, but the invention is not limited in its scope to only dual-damascene structures.

Some embodiments of the invention may be implemented using conventional wet bath apparatuses having voltage polarities, power voltage levels, electrolyte solution compositions, deposition metal source plates, and related process conditions defined in relation to the various applications, interconnect types, and/or the selection of seed metal and metal layer materials.

The term “electro-plating” has been used to generally denote a process whereby metal ions are transferred via an electrolyte solution from a deposition metal source to a target, such as a seed layer, under the influence of an applied electric field. The term might equally be rendered as “electro-deposition” because it is intended to broadly encompass all similarly effective processes. Likewise, the term “electro-polishing” has been used to generally denote a process whereby metal material is removed from a target, such as seed layer, under the influence of an applied electric field. This term might be equally rendered “electro-etching” as it is intended to broadly encompass all similarly effective processes.

In the context of certain embodiments of the invention, the electro-polishing and electro-plating processes may be repeatedly applied to control not only the formation and geometry of the seed layer, but also the geometry and formation of the metal layer. That is, a partially or completely formed metal layer (and/or seed layer) may be subjected to repeated electro-polishing and/or electroplating processes in order to form a desired final product.

The illustrated embodiments are exemplary in nature. Those of ordinary skill in the art will recognize that the invention, as defined by the following claims, is not limited to only the illustrated embodiments. In contrast, it is applicable across a broad range of microelectronic devices, making use of many different kinds of materials—including different metals, and may be performed in its methodological aspects using a variety of conventionally understood fabrication processes and related apparatuses.

What is claimed is:

1. A method of forming a metal interconnect, comprising:
forming an insulation layer on a substrate;
forming a recess in the insulating layer;
forming a seed layer on the recess; and
electro-polishing the seed layer, before filling the recess with metal material.

2. The method of claim 2, further comprising:
before forming the seed layer, forming a diffusion barrier layer on the recess.

3. The method of claim 2, wherein the barrier layer is formed from at least one material selected from a group of materials consisting of: tantalum (Ta), tantalum nitride (TaN), tantalum carbide (TaC), tantalum silicon nitride (TaSiN), titanium nitride (TiN), titanium silicon nitride (TiSiN), tungsten nitride (WN), and tungsten carbide (WC).

4. The method of claim 1, wherein the recess is a trench-via opening comprising a via recess and a trench recess.

5. The method of claim 4, wherein the trench-via recess is a trench first dual damascene opening or a via first dual damascene opening.

6. The method of claim 4, wherein a side surface of the trench-via opening comprises a corner step, and wherein the seed layer is formed more thickly on the corner step than on other portions of the side surface.

7. The method of claim 6, wherein relatively more seed layer material is removed from a portion of the seed layer formed on the corner step than from other portions of the seed layer during electro-polishing of the seed layer.

8. The method of claim 7, wherein the trench-via opening forms an upper corner with an upper surface of the substrate, and wherein the seed layer is formed more thickly on the upper corner than on other portions of the trench-via opening.

9. The method of claim 1, further comprising:
annealing the metal interconnect and thereafter planarizing an upper surface of the substrate.

10. The method of claim 1, wherein the metal material comprises a copper material.

11. A method of forming a metal interconnect in a recess formed in a substrate and prepared with a seed layer, the method comprising:
electro-polishing the seed layer by immersing the substrate in a first electrolyte solution and applying a voltage of first polarity between the substrate and a first deposition metal source plate; and thereafter,
filling the recess with metal material.

12. The method of claim 11, wherein filling the recess with metal material comprises;
applying a voltage of second polarity opposite to the first polarity between the first deposition metal source plate and the substrate immersed in the first electrolyte solution to electro-plate the metal material onto the electro-polished seed layer.

13. The method of claim 11, wherein filling the recess with metal material comprises;
immersing the substrate in a second electrolyte solution and applying a voltage of second polarity opposite the first polarity between the substrate and a second deposition metal source plate to electro-plate the metal material onto the electro-polished seed layer.

14. The method of claim 11, wherein the first electrolyte solution comprises at least one solution component selected from a group of solution components consisting of; phosphorus acid (H3PO3), sulfuric acid (H2SO4), sulphamic acid (H2NSO3H), copper cyanide (CuCN), and pyrophosphate acid (H4P2O7).

15. The method of claim 12, wherein the first electrolyte solution comprises:
at least one solution component selected from a group of solution components consisting of; phosphorus acid (H3PO3), sulfuric acid (H2SO4), CuBF2, sulphamic acid (H2NSO3H), copper cyanide (CuCN), and pyrophosphate acid (H4P2O7); and additionally,
at least one additive selected from a group of additives consisting of; electro-deposition suppressors, electro-deposition brighteners, and levelers.

16. The method of claim 11, wherein the first polarity applies a positive voltage bias to the substrate and a negative voltage bias to the first metal plate.

17. The method of claim 12, wherein the first deposition metal source plate comprises a copper material.

18. The method of claim 13, wherein the second deposition metal source plate comprises a copper material.

19. A method of forming a metal interconnect in a recess formed in a substrate, the recess comprising a bottom surface connected to a sidewall surfaces, and upper corner portions respectively connecting the sidewall surfaces to an upper surface of the substrate, the method comprising:
forming a seed layer of sufficient thickness to completely cover the recess; and thereafter,
electro-polishing the seed layer to a substantially uniform thickness by applying an electric field, the electric field being more concentrated at the upper corner portions of the recess than at the bottom or sidewall surfaces of the recess.

20. The method of claim 19, wherein applying the electric field comprises;
immersing the substrate in a first electrolyte solution and applying a voltage of first polarity between the substrate and a first deposition metal source plate.

21. The method of claim 20, wherein the first electrolyte solution comprises at least one solution component selected from a group of solution components consisting of; phosphorus acid (H3PO3), sulfuric acid (H2SO4), sulphamic acid (H2NSO3H), copper cyanide (CuCN), and pyrophosphate acid (H4P2O7).

22. The method of claim 20, wherein the first polarity applies a positive voltage bias to the substrate and a negative voltage bias to the first deposition metal source plate.

23. The method of claim 22, wherein the first deposition metal source plate comprises a copper material.

24. The method of claim 20, further comprising:
filling the recess with metal material by applying a voltage of second polarity opposite the first polarity between the first deposition metal source plate and the substrate immersed in the first electrolyte solution to electro-plate the metal material onto the electro-polished seed layer.

25. The method of claim 24, wherein the first electrolyte solution comprises:
at least one solution component selected from a group of solution components consisting of; phosphorus acid (H3PO3), sulfuric acid (H2SO4), CuBF2, sulphamic acid (H2NSO3H), copper cyanide (CuCN), and pyrophosphate acid (H4P2O7); and additionally,
at least one additive selected from a group of additives consisting of; electro-deposition suppressors, electro-deposition brighteners, and levelers.

26. The method of claim 20, further comprising:
filling the recess with metal material by immersing the substrate in a second electrolyte solution and applying a voltage of second polarity opposite the first polarity between the substrate and a second deposition metal source plate to electro-plate the metal material onto the electro-polished seed layer.

27. The method of claim 26, wherein the second electrolyte solution comprises at least one solution component selected from a group of solution components consisting of; phosphorus acid (H3PO3), sulfuric acid (H2SO4), sulphamic acid (H2NSO3H), copper cyanide (CuCN), and pyrophosphate acid (H4P2O7).

28. The method of claim 26, wherein the second deposition metal source plate comprises a copper material.

29. The method of claim 19, wherein the recess comprises a trench-via opening, the sidewall surfaces each comprise a corner step portion, and the electric field is more concentrated at the respective step corner portions than at the bottom surface or other portions of the sidewall surfaces.

30. The method of claim 29, wherein the trench-via opening is a trench first dual damascene opening or a via first dual damascene opening.

31. The method of claim 19, wherein the seed layer is formed more thickly on the upper corner portions of the recess than on other portions of recess.

32. The method of claim 31, wherein relatively more seed layer material is removed from portions of the seed layer formed on the upper corner portions than other portions of the seed layer during electro-polishing of the seed layer.

33. The method of claim 29, wherein the seed layer is formed more thickly on the upper corner and step corner portions than on other portions of the trench-via opening.

34. The method of claim 33 wherein relatively more seed layer material is removed from portions of the seed layer formed on the upper corner and step corner portions than from other portions of the seed layer during electro-polishing of the seed layer.

35. The method of claim 19, further comprising:
annealing the metal interconnect and thereafter planarizing an upper surface of the substrate.

36. A method of forming a copper interconnect, comprising:
forming a recess in an insulation layer formed on a substrate;
forming a seed layer of sufficient thickness to completely cover the recess;
selectively removing overhangs formed in the seed layer to produce a polished seed layer having a substantially uniform thickness; and thereafter,
filling the recess with copper material.

37. The method of claim 36, wherein forming the seed layer comprises depositing seed layer material on the recess using a Physical Vapor Deposition (PVD) method.

38. The method of claim 36, wherein selectively removing overhangs formed in the seed layer comprises electro-polishing the seed layer in an electrolyte solution; and
wherein filling the recess with copper material comprises electro-plating the copper material onto the electro-polished seed layer in the electrolyte solution.

39. A copper interconnect formed in a recess, the recess being formed in an insulating layer formed on a substrate, the copper interconnect comprising:
an electro-polished seed layer of substantially uniform thickness formed on bottom and sidewall surfaces of the recess; and
copper material electro-plated onto the electro-polished seed layer to fill the recess.

40. The copper interconnect of claim 39, further comprising:
a diffusion barrier layer formed between the bottom and sidewall surfaces of the recess and the electro-polished seed layer.

41. The copper interconnection of claim 40, wherein the barrier layer is formed from at least one material selected from a group of materials consisting of; tantalum (Ta), tantalum nitride (TaN), tantalum carbide (TaC), tantalum silicon nitride (TaSiN), titanium nitride (TiN), titanium silicon nitride (TiSiN), tungsten nitride (WN), and tungsten carbide (WC).

42. The copper interconnection of claim 39, wherein the seed layer comprises at least one of; essentially pure copper, a copper alloy, and tungsten.

43. The copper interconnection of claim 39, wherein the copper material comprises essentially pure copper.
